(19) United States
(12) Patent Application Publication
(10) Pub. No.: US 2025/0247101 A1
(43) Pub. Date: Jul. 31, 2025

(54) PHASE LOCK LOOP WITH IMPROVED PERFORMANCES AND RELATED METHOD

(71) Applicant: M31 TECHNOLOGY CORPORATION, Hsinchu County (TW)

(72) Inventors: Yen-Yin HUANG, Hsinchu County (TW); Hsiang-En Huang, Hsinchu County (TW)

(21) Appl. No.: 19/034,687

(22) Filed: Jan. 23, 2025

(30) Foreign Application Priority Data
Jan. 30, 2024 (TW) 113103468

(51) Int. Cl. H03L 7/093; H03L 7/095

(52) U.S. Cl. CPC H03L 7/093; H03L 7/095

(57) ABSTRACT

Phase lock loop with improved performances and related method; the former may comprise a first detector, a second detector, a multiplexer, a filter, an oscillator, a frequency-divider and a feedback circuit. The first detector may be coupled to a reference node, a frequency-division node, a first node and a lock-control node. The second detector may be coupled to the reference node, a feedback node and a second node. The multiplexer may be coupled to the first node, the second node, the lock-control node and a filter node. The filter may be coupled to the filter node and a third node. The oscillator may be coupled to the third node and a fourth node. The frequency-divider may be coupled to the fourth node and the frequency-division node. The feedback circuit may be coupled to the reference node, the fourth node, the lock-control node and the feedback node.

This application claims the benefit of Taiwan application Serial No. 113103468, filed Jan. 30, 2024, the subject matter of which is incorporated herein by reference.

### FIELD OF THE INVENTION

The present invention relates to a phase lock loop (PLL) with improved performances and related method, and more particularly, to a PLL and related method wherein the PLL may comprise a first detector, a second detector, a multiplexer, a switch, a filter, an oscillator, a frequency-divider and a feedback circuit, and may rapidly lock frequency and phase.

### BACKGROUND OF THE INVENTION

A phase lock loop is an essential fundamental building block of an integrated circuit.

### SUMMARY OF THE INVENTION

An objective of the invention is providing a phase lock loop (PLL, e.g., 100 in FIG. 1, FIG. 2a and FIG. 2b) with improve performances; the PLL may comprise a first detector (e.g., fd1), a second detector (e.g., pfd2), a multiplexer (e.g., m1), a filter (e.g., 120), an oscillator (e.g., O1), a frequency-divider (e.g., div1) and a feedback circuit (e.g., fb2). The first detector may be coupled to a reference node (e.g., n0), a frequency-division node (e.g., w1), a first node (e.g., n1) and a lock-control node (e.g., nc1). The second detector may be coupled to the reference node, a feedback node (e.g., w2) and a second node (e.g., n2). The multiplexer may comprise two input terminals, a controlled terminal and an output terminal respectively coupled to the first node, the second node, the lock-control node and a filter node (e.g., u1). The filter may be coupled to the filter node and a third node (e.g., n3). The oscillator may be coupled to the third node and a fourth node (e.g., n4). The frequency-divider may be coupled to the fourth node and the frequency-division node. The feedback circuit may be coupled to the reference node, the fourth node, the lock-control node and the feedback node. The reference node may also be coupled to a reference clock (e.g., fref_ck). The filter may provide an oscillation control signal (e.g., s1) at the third node according to a signal at the filter node, and the oscillator may generate an oscillation clock (e.g., dco_ck) at the fourth node according to the oscillation control signal. The frequency-divider may perform frequency division on the oscillation clock to generate a system clock (e.g., sys_ck) at the frequency-division node. The first detector may provide a ready signal (e.g., type1_rdy) at the lock-control node. When the ready signal is of a first level (e.g., v1 in FIG. 2a), the first detector may further detect a frequency difference between the reference clock and the system clock, may provide a first error signal (e.g., fd_err) at the first node according to the frequency difference, and may determine whether to cause the ready signal to change from the first level to a second level (e.g., v2 in FIG. 2a) according to the frequency difference; besides, the multiplexer may conduct (electrically connect) the first node to the filter node. When the ready signal is of the second level, the feedback circuit may provide a feedback clock (e.g., fb_ck) at the feedback node according to the oscillation clock, the second detector may detect a phase difference between the reference clock and the feedback clock to accordingly generate a second error signal (e.g., pfd_err) at the second node, and the multiplexer may conduct (electrically connect) the second node to the filter node.

In an embodiment (e.g., FIG. 1), the filter (e.g., 120) may comprise a first filtering circuit (e.g., H1), a second filtering circuit (e.g., H2) and a third filtering circuit (e.g., H3). The first filtering circuit may be coupled to the filter node (e.g., u1) and a first middle node (e.g., um1). The second filtering circuit may be coupled to a second filter node (e.g., u2) and a second middle node (e.g., um2). The third filtering circuit may be coupled to the first middle node, the second middle node and the third node.

In an embodiment (e.g., FIG. 1, FIG. 2a and FIG. 2b), the PLL may further comprise a switch (e.g., sw1) which may be coupled between the second node and the second filter node. When the ready signal is of the first level, the switch may not electrically connect the second node to the second filter node. When the ready signal is of the second level, the switch may electrically connect the second node to the second filter node.

In an embodiment (e.g., FIG. 2a and FIG. 2b), when the ready signal is of the first level (e.g., as shown in FIG. 2a), the first filtering circuit may perform signal processing (e.g., digital signal processing) on the first error signal (e.g., fd_err) to provide a first filter signal (e.g., sf1 in FIG. 2a) at the first middle node, and the third filtering circuit may form the oscillation control signal (e.g., s1) according to the first filter signal. When the ready signal is of the second level (e.g., as shown in FIG. 2b), the first filtering circuit may perform signal processing (e.g., digital signal processing) on the second error signal (e.g., pfd_err) to provide the first filter signal at the first middle node, the second filtering circuit may perform signal processing (e.g., digital signal processing) on the second error signal to provide a second filter signal (e.g., sf2 in FIG. 2b) at the second middle node, and the third filtering circuit may form the oscillation control signal (e.g., s1) jointly according to the first filter signal and the second filter signal.

In an embodiment (e.g., FIG. 2a and FIG. 2b), when the ready signal is of the first level (e.g., as shown in FIG. 2a), the third filtering circuit may form the oscillation control signal by performing signal processing (e.g., digital signal process) on the first filter signal. When the ready signal is of the second level (e.g., as shown in FIG. 2b), the third filtering circuit may form the oscillation control signal by performing signal processing (e.g., digital signal process) on a linear combination of the first filter signal and the second filter signal (e.g., on a sum of the first filter signal and the second filter signal).

In an embodiment (e.g., FIG. 2d and FIG. 3a), the first detector (e.g., fd1 in FIG. 1 and FIG. 2d) may comprise a reference clock edge detector (e.g., fref_ed in FIG. 2d), a reference clock counter (fref_cnt in FIG. 2d) and a lock detector (e.g., LD1 in FIG. 2d). The reference clock edge detector may be coupled to the reference node (e.g., n0 in FIG. 1 and FIG. 2d), the frequency-division node (e.g., w1 in FIG. 1 and FIG. 2d) and a first connection node (e.g., n31). The reference clock counter may be coupled to the first connection node, a second connection node (e.g., n32 in FIG. 2d) and the frequency-division node. The lock detector may be coupled to the first connection node, the second connection node, the frequency-division node and the lock-control node (e.g., nc1 in FIG. 1 and FIG. 2d). The reference clock edge detector may detect each edge of the reference clock (e.g., fref_ck) occurring when the reference clock changes from a first reference clock level (e.g., va1 in FIG. 3a) to a second reference clock level (e.g., va2 in FIG. 3a), and may accordingly provide an indication signal (e.g., err_det in FIG. 2d) at the first connection node. The reference clock counter may accumulate and reset an internal count (e.g., cnt1 in FIG. 2d) according to the indication signal, and may provide a frequency error signal (e.g., freq_err in FIG. 2d) at the second connection node according to the internal count. The lock detector may control level of the ready signal (e.g., type1_rdy in FIG. 1 and FIG. 2d) according to the frequency error signal. The first detector may provide the first error signal (e.g., fd_err in FIG. 1 and FIG. 2d) according to the frequency error signal.

In an embodiment (e.g., FIG. 3a), when the reference clock edge detector detects each said edge of the reference clock, the reference clock edge detector may cause the indication signal (e.g., err_det in FIG. 2d and FIG. 3a) to change from a first indication level (e.g., vc1 in FIG. 3a) to a second indication level (e.g., vc2 in FIG. 3a), and may cause the indication signal to change back from the second indication level to the first indication level after a first pulse width (e.g., D1 in FIG. 3a).

In an embodiment (e.g., FIG. 3a), the first pulse width may equal a length (e.g., T_sys) of a period of the system clock (e.g., sys_ck in FIG. 1, FIG. 2d and FIG. 3a).

In an embodiment, when the reference clock counter accumulates and resets the internal count according to the indication signal, the reference clock counter may accumulate and reset the internal count according to the indication signal under triggering of the system clock.

In an embodiment, when the reference clock counter provides the frequency error signal according to the internal count, the reference clock counter may cause a current value (e.g., cnt1[i] in FIG. 3b) of the internal count to relate to how many periods of the system clock are included in a corresponding period (e.g., T_ref[i−1] in FIG. 3b) of the reference clock, and may set a current value of the frequency error signal according to the current value of the internal count.

In an embodiment (e.g., FIG. 3b), when the lock detector (e.g., LD1 in FIG. 2d) controls the level of the ready signal according to the frequency error signal, the lock detector may check whether the current value (e.g., freq_err[i] in FIG. 3b) of the frequency error signal (e.g., freq_err in FIG. 3b) causes a predetermined condition to be satisfied, and may accordingly control whether the ready signal (e.g., type1_rdy in FIG. 1 and FIG. 3b) is of the second level (e.g., v2) or the first level (e.g., v1).

In an embodiment (e.g., FIG. 4a), the first detector may comprise a first interior flipflop (e.g., FF1 in FIG. 4a), a second interior flipflop (e.g., FF2 in FIG. 4a), a first interior logic gate (e.g., g1 in FIG. 4a) and a second interior logic gate (e.g., g2 in FIG. 4a). The first interior flipflop may comprise an input terminal, an output terminal and a clock terminal respectively coupled to the reference node, a first interior node (e.g., a1 in FIG. 4a) and the frequency-division node (e.g., w1). The second interior flipflop may comprise an input terminal, an output terminal and a clock terminal respectively coupled to the first interior node, a second interior node (e.g., a2 in FIG. 4a) and the frequency division node. The first interior logic gate may comprise an input terminal and an output terminal respectively coupled to the second interior node and a third interior node (e.g., a3 in FIG. 4a). The second interior logic gate may comprise two input terminals and an output terminal respectively coupled to the third interior node, the first interior node and a fourth interior node (e.g., a4 in FIG. 4a).

In an embodiment (e.g., FIG. 4a), the first interior logic gate may be an AND gate.

In an embodiment (e.g., FIG. 5), the feedback circuit (e.g., fb2 in FIG. 1 or FIG. 5) may comprise a first internal flipflop (e.g., FF51 in FIG. 5), a second internal logic gate (e.g., g52 in FIG. 5) and a third internal logic gate (e.g., g53 in FIG. 5). The first internal flipflop may comprise an input terminal, an output terminal and a clock terminal respectively coupled to the lock-control node (e.g., nc1 in FIG. 1 or FIG. 5), a first front node (e.g., n61 in FIG. 5) and a second front node (e.g., n62 in FIG. 5). The second internal logic gate may comprise an input terminal and an output terminal respectively coupled to the reference node and the second front node. The third internal logic gate may comprise two input terminals and an output terminal respectively coupled to the first front node, the reference node and a first internal node (e.g., n51 in FIG. 5).

In an embodiment (e.g., FIG. 5), the second internal logic gate may be an inverter, and the third internal logic gate may be an AND gate.

In an embodiment (e.g., FIG. 5), the feedback circuit may further comprise a second internal flipflop (e.g., FF52 in FIG. 5) and a third internal flipflop (e.g., FF53 in FIG. 5). The second internal flipflop may comprise a clock terminal coupled to the feedback node. The third internal flipflop may comprise a clock terminal coupled to the fourth node.

In an embodiment (e.g., FIG. 3c), after the ready signal changes from the first level to the second level, the feedback circuit may form a significant edge (e.g., an edge at a time point tb[i+2], FIG. 3c) in the feedback clock (e.g., fb_ck in FIG. 1 and FIG. 3c) in response to an edge (e.g., an edge at a time point tr[i+2], FIG. 3c) of the reference clock (e.g., fref_ck in FIG. 1 and FIG. 3c), and may form a subsequent significant edge (e.g., an edge at a time point tb[i+3], FIG. 3c)) in the feedback clock after a predetermined interval (e.g., T1 in FIG. 3c). Each said significant edge of the feedback clock may be an edge of the feedback clock occurring when the feedback clock changes from a first feedback clock level (e.g., vf1 in FIG. 3c) to a second feedback clock level (e.g., vf2 in FIG. 3c).

In an embodiment (e.g., FIG. 3c), the predetermined interval (e.g., T1) may be a product of a predetermined multiplication number (e.g., N_fb) and a period (e.g., T_dco in FIG. 3c) of the oscillation clock (e.g., dco_ck in FIG. 1 and FIG. 3c)

In an embodiment (e.g., FIG. 3b), when the first detector determines whether to cause the ready signal to change from the first level to the second level according to the frequency difference, the first detector may cause a frequency error signal (e.g., freq_err in FIG. 2d and FIG. 3b) to reflect the frequency difference, and may determine whether to cause the ready signal to change from the first level to the second level according to values (e.g., freq_err[i−1], freq_err[i], freq_err[i+1], etc., FIG. 3b) of the frequency error signal at different periods (e.g., T_ref[i−1], T_ref[i], T_ref[i+1], etc., FIG. 3b) of the reference clock.

An objective of the invention is providing a method for a phase lock loop (e.g., 100 in FIG. 1, FIG. 2a and FIG. 2b). The phase lock loop may comprise an oscillator (e.g., O1 in FIG. 1), the oscillator may generate an oscillation clock (e.g., dco_ck in FIG. 1 and FIG. 3c) according to an oscillation control signal (e.g., s1 in FIG. 1), and the method may comprise: forming a significant edge (e.g., an edge at a time point tb[i+2] in FIG. 3c) in a feedback clock (e.g., fb_ck in FIG. 1 and FIG. 3) in response to an edge (e.g., an edge at a time point tr[i+2], FIG. 3c) of a reference clock (e.g., fref_ck in FIG. 1 and FIG. 3c), and forming a subsequent significant edge (e.g., an edge at a time point tb[i+3], FIG. 3c) in the feedback clock after a predetermined interval (e.g., T1 in FIG. 3c). The method may further comprise: detecting a phase difference between the reference clock and the feedback clock to generate an error signal (e.g., pfd_err in FIG. 1), and providing the oscillation control signal according to the error signal. Each said significant edge of the feedback clock may be an edge of the feedback clock occurring when the feedback clock changes from a first feedback clock level (e.g., vf1 in FIG. 3c) to a second feedback clock level (e.g., vf2 in FIG. 3c).

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 schematically depicts a phase lock loop (PLL) according to an embodiment of the invention, wherein the PLL may comprise a first detector, a filter and a feedback circuit, etc.;

FIG. 2a and FIG. 2b respectively illustrate two operation modes of the PLL shown in FIG. 1;

FIG. 2c schematically depicts the filter in FIG. 1 according to an embodiment of the invention;

according to an embodiment of the invention, FIG. 2d schematically depicts the first detector in FIG. 1, wherein the first detector may comprise a reference clock edge detector, a reference clock counter and a lock detector;

FIG. 3a to FIG. 3c illustrate waveform and timing embodiments of related signals in FIG. 1 and FIG. 2d;

FIG. 4a and FIG. 4b schematically depict embodiments of the reference clock edge generator and the reference counter in FIG. 2d, respectively;

FIG. 5 schematically depicts the feedback circuit in FIG. 1 according to an embodiment; and

FIG. 6 illustrates timing and waveform embodiments of related signals in FIG. 5.

### DETAILED DESCRIPTION OF PREFERRED EMBODIMENTS

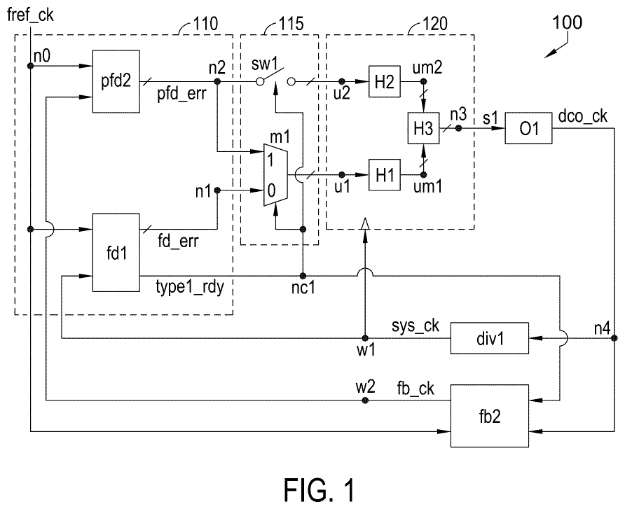

FIG. 1 illustrates a phase lock loop (PLL) 100 according to an embodiment of the invention. The PLL 100 may receive a clock fref_ck as an input, may track and lock frequency and phase timing of the clock fref_ck, and may accordingly output one or more clocks, e.g., a clock dco_ck, which are synchronized with said timing, wherein the clocks fref_ck and dco_ck may be referred to as a reference clock and an oscillation clock, respectively.

The PLL 100 may be disposed in an integrated circuit (not illustrated); for example, the integrated circuit may be a silicon IP (intelligent property) circuit module (e.g., a parallel bus input-output circuit), a processer core, a processor (e.g., a processor for internet of things), a hardware platform, a semiconductor die, a chiplet or a chip; according to the one or more clocks output by the PLL 100, the integrated circuit may control operation timing of interface data input-output, logic operations, signal processing and/or instruction execution, etc.

To balance power consumption and performance, a modern integrated circuit needs to switch between a low-frequency idle state of and a high-frequency performance state. When the integrated circuit switches from the low-frequency idle state to the high-frequency performance state, the PLL in the integrated circuit must consume time and power to lock frequency and phase again, so the PLL can steadily output relocked high-frequency clock(s) for the high-frequency performance state. If the frequency and phase can be locked fast, not only the time and power consumed for relocking frequency and phase can be reduced, but also time required for the integrated circuit to switch between different states can be effectively decreased, so the integrated circuit can switch to the high-frequency performance state more quickly, and can therefore exit the high-frequency performance state earlier to reenter the low-frequency idle state sooner. The PLL 100 of the invention is capable of achieving fast lock of frequency and phase to reduce resources (e.g., time and/or power) consumed for locking frequency and phase, and to effectively satisfy the needs for modern integrated circuit to rapidly switch between states of low-frequency clock(s) and high-frequency clock(s).

As shown in FIG. 1, the PLL 100 of the invention may comprise a detector module 110, a switch module 115, a filter 120, an oscillator O1, a frequency-divider div1 and a feedback circuit fb2. The detector module 110 may comprise two detectors fd1 and pfd2 which may be respectively referred to as a first detector and a second detector. The switch module 115 may be coupled between the detector module 110 and the filter 120, and may comprise a switch sw1 and a multiplexer m1. The filter 120 may be coupled between the switch module 115 and the oscillator O1, and may comprise three filtering circuits H1, H2 and H3 which may be respectively referred to as a first filtering circuit, a second filtering circuit and a third filtering circuit. The frequency-divider div1 may be coupled between the oscillator O1 and the detector module 110; the feedback circuit fb2 may also be coupled between oscillator O1 and the detector module 110.

As shown in FIG. 1, the PLL 100 may be coupled to the clock fref_ck, which may be referred to as the reference clock, at a node n0. The detector fd1 may comprise two input terminals and two output terminals respectively coupled to the node n0 and other three nodes w1, n1 and nc1. The detector pfd2 may comprise two input terminals and an output terminal respectively coupled to the node n0 and other two nodes w2 and n2. The multiplexer m1 may comprise two input terminals, a controlled terminal and an output terminal respectively coupled to the nodes n1, n2, nc1 and another node u1. The switch sw1 may comprise two connection terminals and a controlled terminal respectively coupled to the node n2, another node u2 and the node nc1. The filtering circuit H1 may comprise an input terminal and an output terminal respectively coupled to the node u1 and another node um1. The filtering circuit H2 may comprise an input terminal and an output terminal respectively coupled to the node u2 and another node um2. The filtering circuit H3 may comprise two input terminals and an output terminal respectively coupled to the nodes um1, um2 and another node n3. The oscillator O1 may comprise an input terminal and an output terminal respectively coupled to the node n3 and another node n4. The frequency-divider div1 may comprise an input terminal and an output terminal respectively coupled to the nodes n4 and w1. The feedback circuit fb2 may comprise three input terminals and an output terminal respectively coupled to the nodes n0, nc1, n4 and w2. In the PLL 100, the node n0 may be referred to as a reference node, the nodes n1, n2, n3 and n4 may be respectively referred to as a first node, a second node, a third node and a fourth node, the node w1 may be referred to as a frequency-division node, the node w2 may be referred to as a feedback node, the node nc1 may be referred to as a lock-control node, the nodes u1 and u2 may be respectively referred to as a filter node and a second filter node, and the nodes um1 and um2 may be respectively referred to as a first middle node and a second middle node.

In the PLL 100, the oscillator O1 may generate the clock dco_ck at the node n4 according to a signal s1. The frequency-divider div1 may perform frequency division on the clock dco_ck to generate another clock sys_ck at the node w1. The signal s1 may be referred to as an oscillation control signal, and the clock sys_ck may be referred to as a system clock.

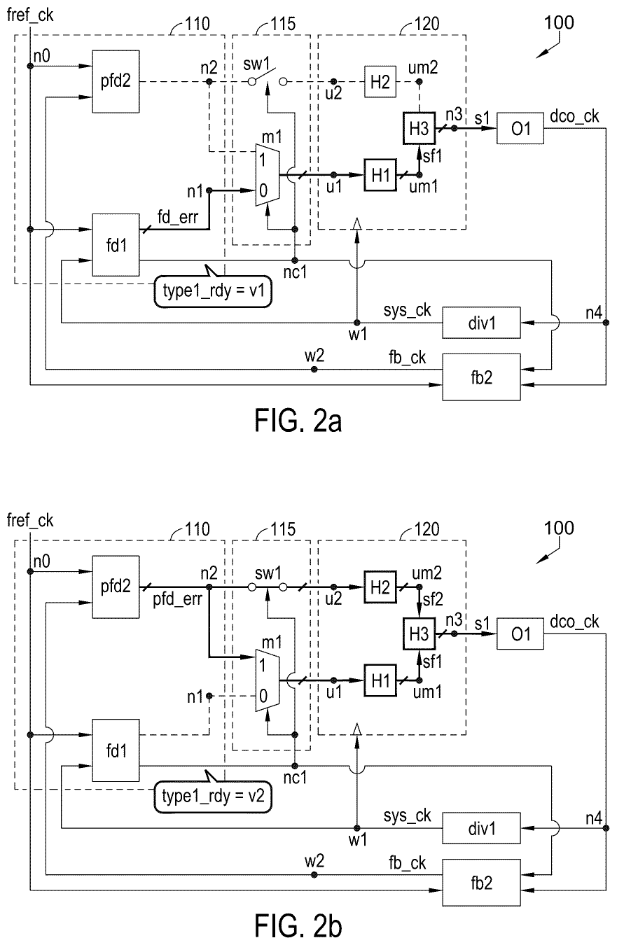

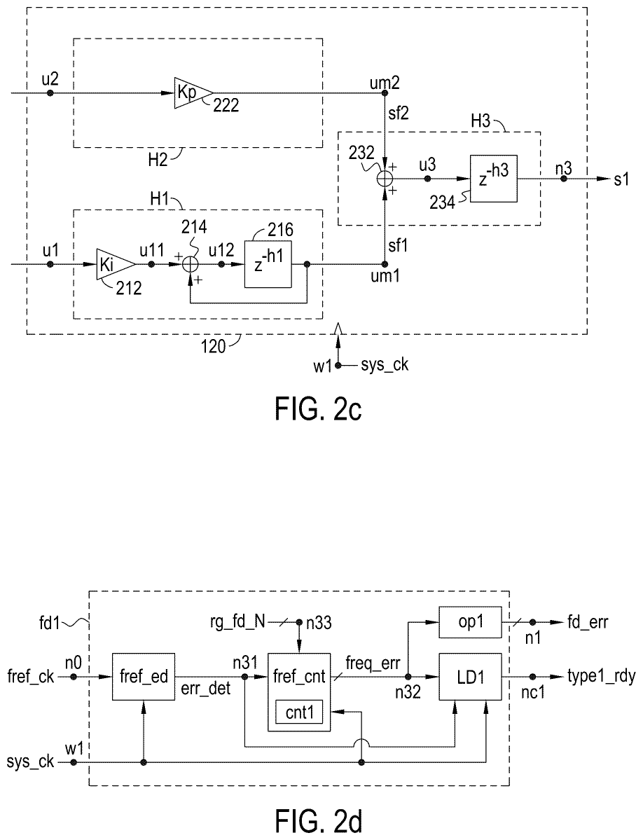

In the PLL 100, the detector fd1 may provide a signal type1_rdy at the node nc1, wherein the signal type1_rdy may be referred to as a ready signal. In an embodiment, a voltage of the signal type1_rdy may change from a level v1 (e.g., a level representing logic 0) to another level v2 (e.g., a level representing logic 1), wherein the levels v1 and v2 may be respectively referred to as a first level and a second level. In an embodiment, when the PLL 100 starts to perform frequency and phase lock, the ready signal type1_rdy may be initialized at the level v1. Following FIG. 1, FIG. 2a and FIG. 2b illustrate operation modes of the PLL 100 when the ready signal type1_rdy is of the levels v1 and v2, respectively. In an embodiment of the invention, the PLL 100 may perform frequency lock by to the mode shown in FIG. 2a, and may perform phase lock by the mode shown in FIG. 2b.

As shown in FIG. 2a, when the ready signal type1_rdy is of the level v1, the detector fd1 may detect a frequency difference between the reference clock fref_ck and the system clock sys_ck, may provide a signal fd_err at the node n1 according to the detected frequency difference, and may also determine whether to cause the signal type1_rdy to change from the level v1 to the level v2 according to the detected frequency difference. When the signal type1_rdy is of the level v1, the multiplexer m1 controlled by the signal type1_rdy may conduct (electrically connect) the node n1 (instead of the node n2) to the node u1, and the switch sw1 also controlled by the signal type1_rdy may not conduct (may not electrically connect) the node n2 to the node u2. Therefore, when the signal type1_rdy is of the level v1, the signal fd_err may be input to the filtering circuit H1 via the nodes n1 and u1; the filtering circuit H1 may perform signal processing on the signal fd_err, and may accordingly provide another signal sf1 at the node um1; the filtering circuit H3 may perform signal processing on the signal sf1, and may form the oscillation control signal s1 according to the signal sf1; the oscillator O1 may control frequency and/or phase of the clock dco_ck according to signal value of the signal s1. In an embodiment, when the ready signal type1_rdy is of the level v1, the filtering circuit H2 may be disabled to stop operation. In FIG. 2a, the signals fd_err and sf1 may be respectively referred to as a first error signal and a first filter signal.

As shown in FIG. 2b, after the detector fd1 causes the ready signal type1_rdy to change to the level v2, the feedback circuit fb2 (also shown in FIG. 1) may provide a clock fb_ck at the node w2 according to the reference clock fref_ck and the oscillation clock dco_ck; the detector pfd2 may detect a phase difference between the reference clock fref_ck and the clock fb_ck, and may generate a signal pfd_err at the node n2 according to the detected phase difference. When the ready signal type1_rdy is of the level v2, the multiplexer m1 controlled by the signal type1_rdy may conduct the node n2 (instead of the node n1) to the node u1, and the switch sw1 also controlled by the signal tyrp1_rdy may conduct the node n2 to the node u2. Thus, when the ready signal type1_rdy is of the level v2, the signal pfd_err may propagate from the node n2 to the nodes u1 and u2 to be input to the filtering circuits H1 and H2, respectively; the filtering circuit H1 may perform signal processing on the signal pfd_err to accordingly provide the signal sf1 at the node um1, the filtering circuit H2 may also perform signal processing on the signal pfd_err to accordingly provide another signal sf2 at the node um2; the filtering circuit H3 may form the oscillation control signal s1 jointly according to the signals sf1 and sf2, and the oscillator O1 may control frequency and/or phase of the clock dco_ck according to the signal value of the signal s1. In an embodiment, the filtering circuit H3 may perform signal processing on a linear combination of the signals sf1 and sf2 (e.g., a sum (sf1+sf2) of the signals sf1 and sf2) to form the signal s1. In FIG. 2b, the clock fb_ck may be referred to as a feedback clock, the signal pfd_err may be referred to as a second error signal, and the signal sf2 may be referred to as a second filter signal.

In an embodiment of the invention, the filter 120 may be a digital filter, and the filtering circuits H1, H2 and H3 may be digital filtering circuits; the filter 120 (and the filtering circuits H1 to H3) may be further coupled to the clock sys_ck at the node w1, and may perform digital filtering (e.g., digital signal processing) to provide the digital signal s1 under triggering of the clock sys_ck. Correspondingly, the oscillator O1 may be a digitally controlled oscillator.

According to an embodiment of the invention, FIG. 2c illustrates the filtering circuits H1 to H3 in the filter 120. In this embodiment, the filtering circuit H1 may further comprise a multiplier 212, an adder 214 and a delayer 216, the filtering circuit H2 may further comprise a multiplier 222, and the filtering circuit H3 may further comprise an adder 232 and a delayer 234. In the filtering circuit H1, the multiplier 212 may comprise an input terminal and an output terminal respectively coupled to the node u1 and another node u11, the adder 214 may comprise two input terminals and an output terminal respectively coupled to the nodes u11, um1 and another node u12, the delayer 216 may comprise an input terminal and an output terminal respectively coupled to the nodes u12 and um1. The multiplier 212 may multiply a signal value at the node u1 by a number Ki, and may output a result of the multiplication to the node u11. The adder 214 may summarize signal values at the nodes u11 and um1, and may output a resultant sum to the node u12. The delayer 216 may delay a signal at the node u12 by a number h1 of unit intervals, and may output delayed signal to the node um1, wherein a unit interval may be as long as a period of the system clock sys_ck, and the number h1 may be a predetermined constant, e.g., an integer greater than or equal to integer one. In an embodiment, the number h1 may equal integer one.

In the filtering circuit H2, the multiplier 222 may comprise an input terminal and an output terminal respectively coupled to the nodes u2 and um2; the multiplier 222 may multiply signal value at the node u2 by a number Kp, and may output a result of the multiplication to the node um2. In the filtering circuit H3, the adder 232 may comprise two input terminals and an output terminal respectively coupled to the nodes um1, um2 and another node u3, and the delayer 234 may comprise an input terminal and an output terminal respectively coupled to the nodes u3 and n3. The adder 232 may summarize signal values at the nodes um1 and um2, and may output a resultant sum to the node u3. The delayer 234 may delay a signal at the node u3 by a number h3 of unit intervals, and output delayed signal to the node n3, wherein a unit interval may be as long as a period of the system clock sys_ck, and the number h3 may be a predetermined constant, e.g., an integer greater than or equal to one.

According to the embodiment shown in FIG. 2c, when the ready signal type1_rdy is of the level v2 (as shown in FIG. 2b), the filtering circuit H3 may perform signal processing on a sum (sf1+sf2) of the signals sf1 and sf2 to form the oscillation control signal s1. The filtering circuits H1, H2 and H3 may have various embodiments, and what is shown in FIG. 2c is merely one of the various embodiments. Furthermore, besides the filtering circuits H1, H2 and H3, the filter 120 may further comprise other circuit(s) not depicted, such as an enabling control circuit which may disable the filtering circuit H2 when the signal type1_rdy is of the level v1, and may enable the filtering circuit H2 when the signal type1_rdy is of the level v2.

FIG. 2d illustrates an embodiment of the detector fd1 in FIG. 1 by a schematic diagram. As shown in FIG. 2d, the detector fd1 may further comprise a reference clock edge detector fref_ed, a reference clock counter fref_cnt, a lock detector LD1 and an output circuit op1. The reference clock edge detector fref_ed may comprise two input terminals and an output terminal respectively coupled to the reference node n0, the frequency-division node w1 (also shown in FIG. 1) and another node n31. The reference clock counter fref_cnt may comprise three input terminals and an output terminal respectively coupled to the frequency-division node w1, the node n31 and two other nodes n33 and n32. The lock detector LD1 may comprise three input terminals and an output terminal respectively coupled to the nodes n31 and n32, the frequency-division node w1 and the lock-control node nc1 (also shown in FIG. 1). The output circuit op1 may comprise an input terminal and an output terminal respectively coupled to the nodes n32 and n1 (also shown in FIG. 1). The node n33 may be further coupled to a number rg_fd_N which may be a predetermined constant, e.g., an integer greater than one. The number rg_fd_N may be referred to as an initial value. In the detector fd1, the nodes n31, n32 and n33 may be referred to as a first connection node, a second connection node and a third connection node, respectively.

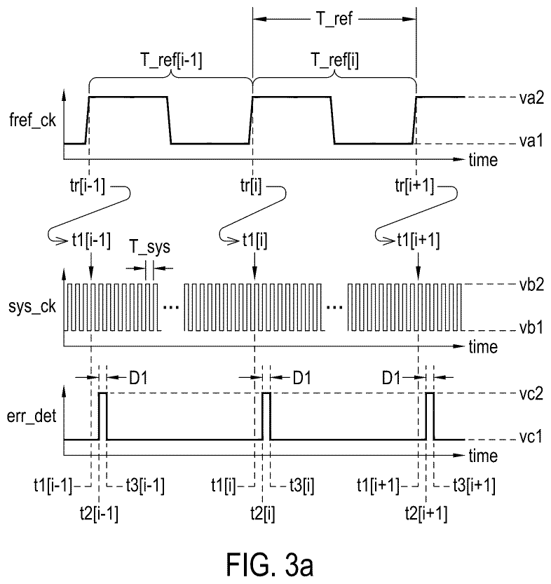

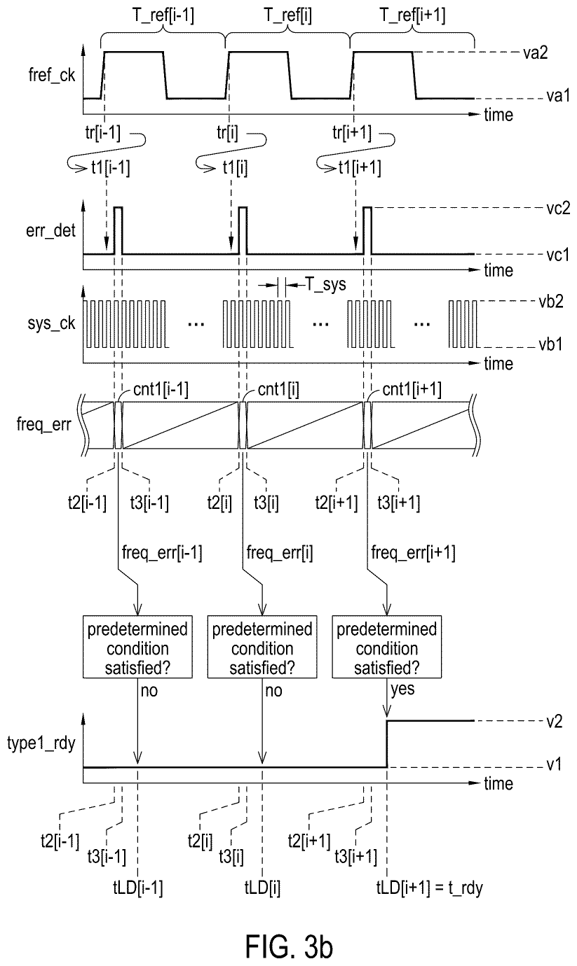

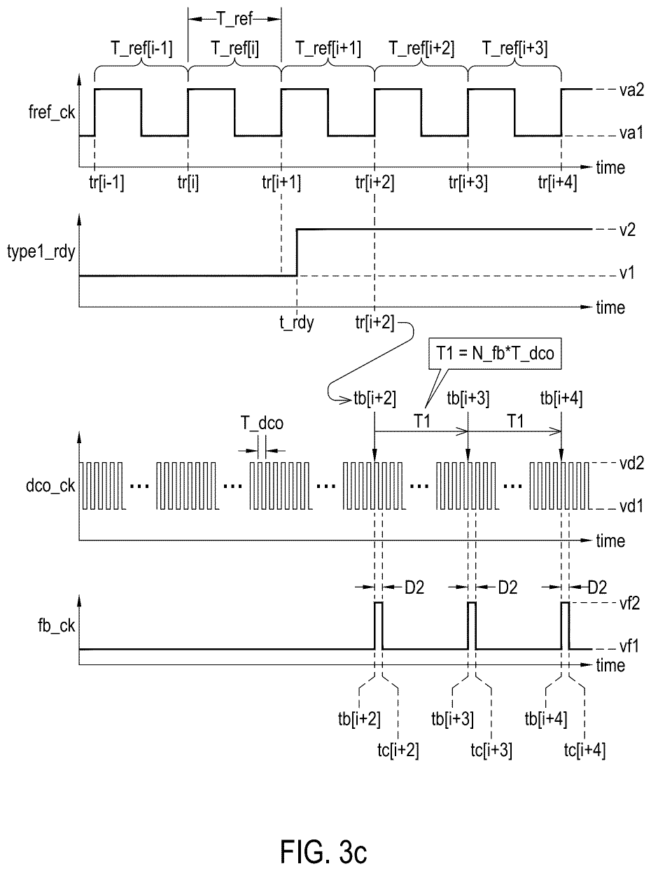

FIG. 3a to FIG. 3c illustrate timing and waveform embodiments of related signals shown in FIG. 1 and FIG. 2d. As shown in FIG. 3a, the reference clock fref_ck may oscillate between two different levels va1 and va2 alternately. The levels va1 and va2 may be two levels representing logic 0 and logic 1, and may be referred to as a first reference clock level and a second reference clock level, respectively. An edge occurring when the reference clock fref_ck changes from the levels va1 to va2 may be referred to as a significant edge of the reference clock fref_ck, and an interval between two consecutive significant edges of the reference clock fref_ck may be a period of the reference clock fref_ck. FIG. 3a shows three time points tr[i−1], tr[i] and tr[i+1] which may respectively represent three successive significant edges of the reference clock fref_ck; an interval from the time points tr[i−1] to tr[i] may be a period T_ref[i−1] of the reference clock fref_ck, and an interval from the time points tr[i] to tr[i+1] may be a next period T_ref[i] of the reference clock fref_ck. A time length of each period of the reference clock fref_ck may be represented by a period length T_ref.

The system clock sys_ck may oscillate between two different levels vb1 and vb2 alternatingly. The levels vb1 and vb2 may be two levels representing logic 0 and logic 1, and may be referred to as a first system clock level and a second system clock level, respectively. An edge occurring when the system clock sys_ck changes from the levels vb1 to vb2 may be referred to as a significant edge of the clock sys_ck, and an interval between two consecutive significant edges of the clock sys_ck may be a period of the clock sys_ck, wherein a time length of the period of the clock sys_ck may be represented by a period length T_sys. In an embodiment, the period length T_sys of the clock sys_ck may be shorter than the period length T_ref of the clock fref_ck.

In FIG. 3a, a time point t1[i−1] may represent a nearest significant edge of the clock sys_ck which occurs right after the time point tr[i−1], and another two time points t2[i−1] and t3[i−1] may represent next two significant edges of the clock sys_ck after the time point t1[i−1]. Similarly, a time point t1[i] may represent a nearest significant edge of the clock sys_ck occurring after the time point tr[i], and another two time points t2[i] and t3[i] may represent next two significant edges of the clock sys_ck after the time point t1[i]. Moreover, a time point t1[i+1] may represent a nearest significant edge of the clock sys_ck occurring right after the time point tr[i+1], and another two time points t2[i+1] and t3[i+1] may represent next two significant edges of the clock sys_ck after the time point t1[i+1].

In the detector fd1 shown in FIG. 2d, the reference clock edge detector fref_ed may detect each significant edge of the reference clock fref_ck occurring whenever the clock fref_ck changes from the levels va1 to va2, and may accordingly provide a signal err_det, which may be referred to as an indication signal, at the node n31. The reference clock counter fref_cnt may accumulate and reset a count cnt1 according to the signal err_det, and may provide a signal freq_err at the node n32 according to the count cnt1; the count cnt1 and the signal freq_err may be respectively referred to as an internal count and a frequency error signal. The lock detector LD1 may control level of the ready signal type1_rdy (also shown in FIG. 1, FIG. 2a and FIG. 2b) according to the signal freq_err. The output circuit op1 may generate the first error signal fd_err (also shown in FIG. 1, FIG. 2a and FIG. 2b) according to the signal freq_err; for example, the output circuit op1 may perform signal processing on the signal freq_err (e.g., multiplying by a first predetermined value and/or adding a second predetermined value, etc.), and may output processed signal as the signal fd_err.

As shown in FIG. 3a, the reference clock edge detector fref_ed in FIG. 2d may detect significant edges of the reference clock fref_ck under triggering of the system clock sys_ck; when a significant edge of the reference clock fref_ck is detected, the reference clock edge detector fref_ed may form a pulse in the indication signal err_det, e.g., may cause the signal err_det to change from a level vc1 to another level vc2, and may then cause the signal err_det to change back from the levels vc2 to vc1 after a pulse width D1. The levels vc1 and vc2 may be two levels representing logic 0 and logic 1, and may be referred to as a first indication level and a second indication level, respectively. In an embodiment, the pulse width D1 may equal the period length T_sys of the system clock sys_ck. According to an embodiment of the invention, the reference clock edge detector fref_ed may sample the clock fref_ck at each significant edge of the clock sys_ck; when the reference clock edge detector fref_ed samples the clock fref_ck at a current significant edge of the clock sys_ck and obtains a current sampled result, the reference clock edge detector fref_ed may determine whether a significant edge of the clock fref_ck is detected according to whether the current sampled result and a preceding sampled result respectively represent logic 1 and logic 0, wherein the preceding sampled result may be a sampled result obtained when the reference clock edge detector fref_ed samples the clock fref_ck at a preceding significant edge of the clock sys_ck.

As shown in FIG. 3a, when the reference clock edge detector fref_ed samples the clock fref_ck at the time point t1[i−1] of the significant edge of the clock sys_ck, the reference clock edge detector fref_ed may detect the significant edge of the clock fref_ck occurring at the time point tr[i−1]; in response to this detected result, the reference clock edge detector fref_ed may cause the signal err_det to change from the levels vc1 to vc2 at the time point t2[i−1] of the next significant edge of the clock sys_ck, and may then cause the signal err_det to change back from the levels vc2 to vc1 after the pulse width D1, e.g., may then cause the signal err_det to change back from the levels vc2 to vc1 at the time point t3[i−1] of another significant edge of the clock sys_ck.

Similarly, at the time point t1[i] of the significant edge of the clock sys_ck, the reference clock edge detector fref_ed may detect the significant edge of the clock fref_ck occurring at the time point tr[i], so the reference clock edge detector fref_ed may cause the signal err_det to change from the levels vc1 to vc2 at the time point t2[i] of the next significant edge of the clock sys_ck, and may then cause the signal err_det to change back from the levels vc2 to vc1 after the pulse width D1 (e.g., at the time point t3[i]). Again, at the time point t1[i+1] of the significant edge of the clock sys_ck, the reference clock edge detector fref_ed may detect the significant edge of the clock fref_ck occurring at the time point tr[i+1], so the reference clock edge detector fref_ed may cause the signal err_det to change from the levels vc1 to vc2 at the time point t2[i+1] of the succeeding significant edge of the clock sys_ck, and may then cause the signal err_det to change back from the levels vc2 to vc1 after the pulse width D1 (e.g., at the time point t3[i+1]).

According to an embodiment of the invention, the reference clock counter fref_cnt in FIG. 2d may control (e.g., may accumulate and reset) value of the count cnt1 according to the indication signal err_det under triggering of the system clock sys_ck, and may provide the signal freq_err according to the count cnt1, as shown in FIG. 3b. In the embodiment shown in FIG. 3b, in response to that the indication signal err_det is of the level vc2 between the time points t2[i] and t3[i], the reference clock counter fref_cnt may cause a current value cnt1[i] of the count cnt1 to relate to how many period lengths T_sys of the system clock sys_ck are included in the corresponding period T_ref[i−1] of the clock fref_ck, and may set a current value freq_err[i] of the signal freq_err according to the current value cnt1[i].

Briefly speaking, in response to that the signal err_det is of the level vc2 (e.g., from the time points t2[i] to t3[i]), the reference clock counter fref_cnt may cause a current value (e.g., cnt1[i]) of the count cnt1 to reflect (to relate to) how many period lengths T_sys are included in (have elapsed during) a corresponding period (e.g., T_ref[i−1]) of the reference clock fref_ck, and may set a current value (e.g., freq_err[i]) of the signal freq_err according to the current value of the count cnt1.

As shown in FIG. 3b, during the period T_ref[i−1] of the clock fref_ck, in response to that the indication signal err_det changes from the levels vc1 to vc2 at the time point t2[i−1], the lock detector LD1 in FIG. 2d may check whether a value freq_err[i−1] of the signal freq_err between the time points t2[i−1] and t3[i−1] causes a predetermined condition to be satisfied, and may accordingly control whether the ready signal type1_rdy is of the level v1 or v2; for example, if the value freq_err[i−1] does not cause the predetermined condition to be satisfied, the lock detector LD1 may set the ready signal to the level v1 at a time point tLD [i−1] after the time point t3[i−1]. After the time point tLD [i−1], during the next period T_ref[i] of the clock fref_ck, in response to that the indication signal err_det changes from the levels vc1 to vc2 again at the time point t2[i], the lock detector LD1 may check whether the value freq_err[i] of the signal freq_err between the time points t2[i] and t3[i] causes the predetermined condition to be satisfied, and may according control whether the ready signal type1_rdy should be of level v1 or v2; for example, if the value freq_err[i] of the signal freq_err still fails to cause the predetermined condition to be satisfied, the lock detector LD1 may continue to set the ready signal type1_rdy to the level v1 at a time point tLD [i] after the time point t3[i].

After the time point tLD [i], during the succeeding period T_ref[i+1] of the clock fref_ck, in response to that the indication signal err_det changes from the levels vc1 to vc2 once again at the time point t2[i+1], the lock detector LD1 may check whether a value freq_err[i+1] of the signal freq_err between the time points t2[i+1] and t3[i+1] causes the predetermined condition to be satisfied, and may according control whether the ready signal type1_rdy should be of level v1 or v2; for example, if the value freq_err[i] of the signal freq_err successfully causes the predetermined condition to be satisfied, the lock detector LD1 may set the ready signal type1_rdy to the level v2 at a time point tLD [i+1] after the time point t3[i+1], i.e., may cause the signal type1_rdy to change from the levels v1 to v2 at the time point tLD [i+1]. For convenience of description, the time point tLD [i+1] is referred to as a time point t_rdy hereinafter.

According to an embodiment of the invention, the predetermined condition of the lock detector LD1 may reflect whether the PLL 100 (FIG. 1) achieves frequency lock. For example, in response to that the indication signal err_det changes to the level vc2 at the time point t2[i+1], the lock detector may check whether the value freq_err[i+1] of the signal freq_err falls in a predetermined range; if the value freq_err[i+1] of the signal freq_err falls in the predetermined range, and each of a predetermined number of preceding values, e.g., freq_err[i], freq_err[i−1] and freq_err[i−2] (not depicted) also falls in the predetermined range, then the lock detector LD1 in the detector fd1 (FIG. 2d) may determine that the predetermined condition is satisfied, and may cause the ready signal type1_rdy to change from the levels v1 to v2 to reflect that the PLL 100 reaches frequency lock. As earlier descripted by referring FIG. 2a and FIG. 2b, when the ready signal type1_rdy is of the level v1, i.e., before the time point t_rdy, the PLL 100 may operate according to the mode shown in FIG. 2a to lock frequency; after the time point t_rdy when PLL 100 achieves frequency lock, the detector fd1 may cause the ready signal type1_rdy to change to the level v2, so the PLL 100 may operate according to the mode show in FIG. 2b to lock phase.

FIG. 3c illustrates waveform and timing embodiments of signals related to the feedback circuit fb2 shown in FIG. 1. In FIG. 3c, time points tr[i+2], tr[i+3] and tr[i+4] may respectively represent three closest significant edges of the clock fref_ck after the time point tr[i+1] of the significant edge of the clock fref_ck, and intervals from the time points tr[i+1] to tr[i+2], time points tr[i+2] to tr[i+3] and time points tr[i+3] to tr[i+4] may respectively be three periods T_ref[i+1], T_ref[i+2] and T_ref[i+3] of the clock fref_ck. As shown in

FIG. 3c, the clock dco_ck may oscillate alternatingly between two different levels vd1 and vd2. The levels vd1 and vd2 may be two levels representing logic 0 and logic 1, and may be referred to as a first oscillation clock level and a second oscillation clock level, respectively. An edge occurring when the clock dco_ck changes from the levels vd1 to vd2 may be referred to as a significant edge of the clock dco_ck. A time length of a period of the clock dco_ck may be represented by a period length T_dco; in an embodiment, the period length T_dco may be shorter than the period length T_sys of the clock sys_ck.

As shown in FIG. 3c, when the signal type1_rdy stays at the level v1, the feedback circuit fb2 may cause a voltage of the clock fb_ck to stay at a level vf1. After the signal type1_rdy changes from the levels v1 to v2 at the time point t_rdy following the time point tr[i+1], in response to the next significant edge of the reference clock fref_ck at the time point tr[i+2], the feedback circuit fb2 may cause the clock fb_ck to change from the level vf1 to another level vf2 at a time point tb[i+2] to form a significant edge in the clock fref_ck, and may cause the clock fb_ck to change back from the levels vf2 to vf1 at another time point tc[i+2] after a predetermined pulse width D2 (i.e., at time point (tb[i+2]+D2)), so as to form a pulse in the clock fb_ck. The levels vf1 and vf2 may be two levels representing logic 0 and logic 1, and may be referred to as a first feedback clock level and a second feedback clock level, respectively; an edge occurring when the clock fb_ck changes from the level vf1 to vf2 may be referred to as a significant edge of the clock fb_ck.

In other words, after the time point t_rdy, in response to the significant edge of the clock fref_ck at the time point tr[i+2], the feedback circuit fb2 may form the significant edge and the pulse of the clock fb_ck at the time point tb[i+2]. After the significant edge and the pulse of the clock fb_ck at the time point tb[i+2], the feedback circuit fb2 may further form a significant edge and a pulse in the clock fb_ck regularly at a predetermined interval T1. As shown in FIG. 3c, following the significant edge of the clock fb_ck at the time point tb[i+2], the feedback circuit fb2 may form a next significant edge in the clock fb_ck at a time point tb[i+3] after the predetermined interval T1 (i.e., at time point (tb[i+2]+T1)), and may cause the clock fb_ck to change back to the level vf1 to form a pulse at another time point tc[i+3] after the pulse width D2 (i.e., at time point (tb[i+3]+D2)). Similarly, following the significant edge of the clock fb_ck at the time point tb[i+3], the feedback circuit fb2 may form a subsequent significant edge in the clock fb_ck at a time point tb[i+4] after the predetermined interval T1 (i.e., at time point (tb[i+3]+T1)), and may cause the clock fb_ck to change back to the level vf1 to form a pulse at another time point tc[i+4] after the pulse width D2 (i.e., at time point (tb[i+4]+D2)). That is, after the time point tb[i+2], the feedback circuit fb2 may form a periodic pulse train in the clock fb_ck, and a repetition period of the pulses may equal the predetermined interval T1.

In an embodiment, the feedback circuit fb2 may form the pulses in the clock fb_ck under triggering of the clock dco_ck. For example, the time point tb[i+2] may represent a nearest significant edge of the clock dco_ck occurring after the time point tr[i+2], the pulse width D2 may equal the period length T_dco of the clock dco_ck, and the predetermined interval T1 may equal a product of a number N_fb and the period length T_dco (i.e., T1=N_fb*T_dco); in other words, the time points tc[i+2], tb[i+3], tc[i+3], tb[i+4] and tc[i+4] may respectively represent different significant edges of the clock dco_ck. For example, the time point tb[i+3] may represent a significant edge of the clock dco_ck occurring when the number N_fb of the period lengths T_dco have elapsed after the time point tb[i+2]. The number N_fb may be a predetermined constant, e.g., a constant greater than one; the number N_fb may be referred to as a predetermined multiplication number.

According to an embodiment of the invention, when the PLL 100 operates according to FIG. 2b after the time point t_rdy, the detector pfd2 may detect time differences between time points of the significant edges of the clock fref_ck and time points of corresponding significant edges of the clock fb_ck, such as the time difference between the time points tr[i+2] and tb[i+2], the time difference between the time points tr[i+3] and tb[i+3], and the time difference between the time points tr[i+4] and tb[i+4], etc., and the detector pfd2 may therefore generate the signal pfd_err in FIG. 1. In an embodiment, the detector pfd2 may be a bang-bang phase detector. In an embodiment, the detector pfd2 may comprise a time-to-digital converter (TDC).

When the PLL 100 in FIG. 1 performs frequency lock according to FIG. 2a before the time point t_rdy, the PLL 100 may achieve frequency lock rapidly based on setting of a gain K_dco (not depicted) of the oscillator O1. As shown in FIG. 2a, when the oscillator O1 generates the clock dco_ck according to the signal s1, the period length T_dco of the clock dco_ck may relate to (e.g., positively correlate to) a product of the gain K_dco and the signal s1. Because an expect value (a target value) of the period length T_dco, an expected value of the period length T_sys and an expected value of the period length T_ref are known, an expected value of the signal fd_err is known; in addition, because a transfer function, which is applied by the filter 120 when providing the signal s1 according to the signal fd_err, is also known, an expected value of the signal s1 is then known. Therefore, under an arrangement coordinating the expected values of the gain K_dco, the signal s1 and the period length T_dco, the PLL 100 may rapidly achieve frequency lock.

When the PLL 100 accomplishes frequency lock according to the mode shown in FIG. 2a, the PLL 100 may already cause the period length T_ref of the reference clock fref_ck, the period length T_sys of the system clock sys_ck and the period length T_dco of the oscillation clock dco_ck to match a predetermined multiplication relation. The number N_fb of the feedback circuit fb2 may also be set according to the predetermined multiplication relation. Therefore, when the PLL 100 operates according to FIG. 2b, the feedback circuit fb2 may cause the predetermined interval T1 to substantially equal the period length T_ref (or may cause an error between the predetermined interval T1 and the period length T_ref not to be greater than a predetermined time error).

As shown in FIG. 3c, because the significant edge of the clock fb_ck occurring at the time point tb[i+2] is formed by the feedback circuit fb2 in response to the significant edge of the clock fref_ck at the time point tr[i+2], the two significant edges are already quite near, and therefore the phase difference between the clocks fb_ck and fref_ck are already quite small. In addition, because the predetermined interval T1 and the period length T_ref are also substantially equal or very close, subsequent significant edges of the clock fref_ck (e.g., the significant edge at the time point tr[i+3]) and corresponding subsequent significant edges of the clock fb_ck (e.g., the significant edge at the time point tb[i+3]) will also be very near. Therefore, after the PLL 100 accomplishes fast frequency lock according to FIG. 2a, the PLL 100 may also accomplish fast phase lock according to FIG. 2b.

Briefly speaking, the PLL 100 of the invention may first accomplish rapid frequency lock according to FIG. 2a, and then may accomplish rapid phase lock according to FIG. 2b. Because the PLL 100 of the invention may rapidly achieve frequency and phase lock, time and/or power consumed by frequency and phase lock may be effectively reduced, and demands for modern integrated circuit to rapidly switch between low-frequency idle state and high-frequency performance state may be satisfied.

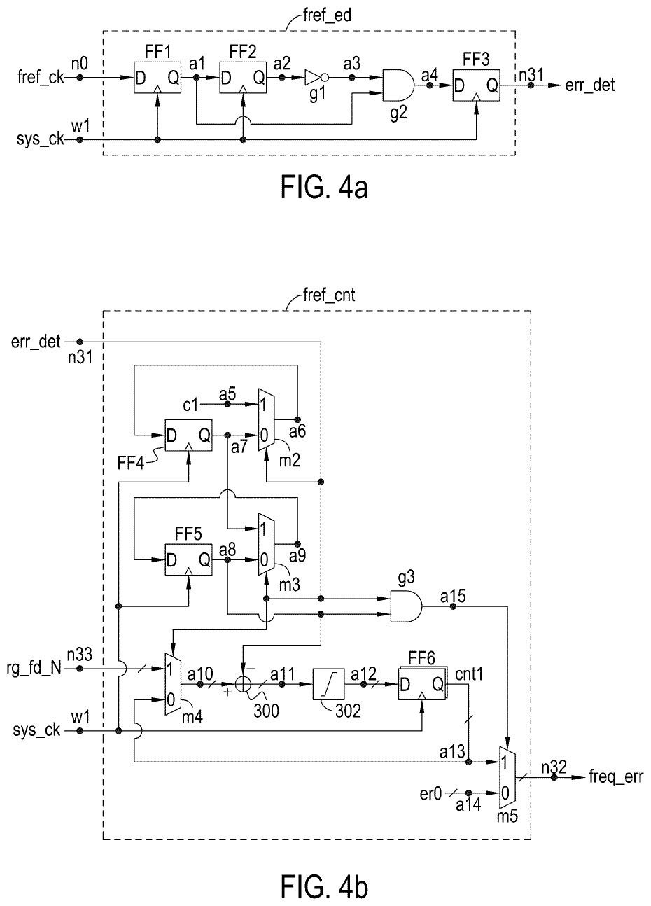

FIG. 4a illustrates an embodiment of the reference clock edge detector fref_ed shown in FIG. 2d. As shown in FIG. 4a, the reference clock edge detector fref_ed may further comprise three flipflops FF1, FF2 and FF3, and two logic gates g1 and g2. The flipflop FF1 may comprise an input terminal (labeled by “D”), an output terminal (labeled by “Q”) and a clock terminal respectively coupled to the reference clock fref_ck at the node n0, another node a1 and the system clock sys_ck at the node w1. The flipflop FF2 may comprise an input terminal, an output terminal and a clock terminal respectively coupled to the node a1, another node a2 and the system clock sys_ck at the node w1. The logic gate g1 may comprise an input terminal and an output terminal respectively coupled to the node a2 and another node a3; in an embodiment, the logic gate g1 may be an inverter. The logic gate g2 may comprise two input terminals and an output terminal respectively coupled to the nodes a1, a3 and another node a4; in an embodiment, the logic gate g2 may be an AND gate. The flipflop FF3 may comprise an input terminal, an output terminal and a clock terminal respectively coupled to the nodes a4, n31 (also shown in FIG. 2d) and the system clock sys_ck at the node w1.

In the reference clock edge detector fref_ed, the flipflop FF1 may sample the clock fref_ck at every significant edge of the system clock sys_ck; if a result of the sampling is the level va1 (FIG. 3a), the flipflop FF1 may cause a logic value at the node a1 to be logic 0; if the result of the sampling is the level va2 (FIG. 3a), the flipflop FF1 may cause the logic value at the node a1 to be logic 1. At each significant edge of the system clock sys_ck, the flipflop FF2 may sample the logic value at the node a1, and may keep outputting a result of the sampling to the node a2 until a next significant edge of the clock sys_ck. At every significant edge of the system clock sys_ck, the flipflop FF3 may sample a logic value at the node a4; if a result of the sampling is logic 0, the flipflop FF3 may cause the signal err_det at the node n31 to be the level vc1 (FIG. 3a); if the result of the sampling is logic 1, the flipflop FF3 may cause the signal err_det to be the level vc2 (FIG. 3a).

FIG. 4b illustrates an embodiment of the reference clock counter fref_cnt shown in FIG. 2d. As shown in FIG. 4b, the reference clock counter fref_cnt may further comprise three flipflops FF4, FF5 and FF6, four multiplexers m2, m3, m4 and m5, a logic gate g3, an adder 300 and a saturation circuit 302. The multiplexer m2 may comprise two input terminals, an output terminal and a controlled terminal respectively coupled to three nodes a5, a7, a6 and the signal err_det (also shown in FIG. 2d, FIG. 3a and FIG. 3b) at the node n31. When the signal err_det is of the level vc2 (FIG. 3a and FIG. 3b), the multiplexer m2 may conduct (electrically connect) the node a5 (instead of the node a7) to the node a6; when the signal err_det is of the level vc1, the multiplexer m2 may conduct the node a7 (instead of the node a5) to the node a6. The node a5 may be further coupled to a number c1; the number c1 may be a predetermined constant, e.g., the number c1 may equal integer one. The multiplexer m3 may comprise two input terminals, an output terminal and a controlled terminal respectively coupled to the node a7, another two nodes a8 and a9, and the signal err_det at the node n31. When the signal err_det is of the level vc2, the multiplexer m3 may conduct the node a7 (instead of the node a8) to the node a9; when the signal err_det is of the level vc1, the multiplexer m3 may conduct the node a8 (instead of the node a7) to the node a9. The multiplexer m4 may comprise two input terminals, an output terminal and a controlled terminal respectively coupled to the number rg_fd_N (also shown in FIG. 2d) at the node n33, another two nodes a13 and a10, and the signal err_det at the node n31. When the signal err_det is of the level vc2, the multiplexer m4 may conduct the node n33 (instead of the node a13) to the node a10; when the signal err_det is of the level vc1, the multiplexer m4 may conduct the node a13 (instead of the node n33) to the node a10. The multiplexer m5 may comprise two input terminals, an output terminal and a controlled terminal respectively coupled to the node a13, another node a14, the node n32 (also shown in FIG. 2d) and still another node a15; when a logic value at the node a15 is logic 1, the multiplexer m5 may conduct the node a13 (instead of the node a14) to the node n32; when the logic value at the node a15 is logic 0, the multiplexer m5 may conduct the node a14 (instead of the node a13) to the node n32. The node a14 may be further coupled to a number er0; in an embodiment, the number er0 may be a predetermined constant. A signal value at the node a13 may be the count cnt1 (also shown in FIG. 2d).

As shown in FIG. 4b, the flipflop FF4 may comprise an input terminal, an output terminal and a clock terminal respectively coupled to the node a6, the node a7 and the clock sys_ck at the node w1. The flipflop FF5 may comprise an input terminal, an output terminal and a clock terminal respectively coupled to the node a9, the node a8 and the clock sys_ck at the node w1. The flipflop FF6 may comprise an input terminal, an output terminal and a clock terminal respectively coupled to a node a12, the node a13 and the clock sys_ck at the node w1. In the reference clock counter fref_cnt shown in FIG. 4b, each of the flipflops FF4 to FF6 may sample a signal at its input terminal at each significant edge of the system clock sys_ck, and may keep outputting a result of the sampling to its output terminal until a next significant edge of the system clock sys_ck.

As shown in FIG. 4b, the logic gate g3 may comprise two input terminals and an output terminal respectively coupled to the signal err_det at the node n31, the node a8 and the node a15; in an embodiment, the logic gate g3 may be an AND gate. The adder 300 may comprise two input terminals and an output terminal respectively coupled to the node a8, the node a10 and another node a11; the adder 300 may subtract a signal value at the node a8 from a signal value at the node a10, and output a result of the subtraction to the node a11. The saturation circuit 302 may comprise an input terminal and an output terminal respectively coupled to the nodes a11 and a12. If a signal value at the node a11 is between an upper bound (not depicted) and a lower bound (not depicted), the saturation circuit 302 may output the signal value at the node a11 to the node a12; if the signal value at the node a11 is greater than the upper bound or less than the lower bound, the saturation circuit 302 may cause a signal value at the node a12 to equal the upper bound or the lower bound, respectively.

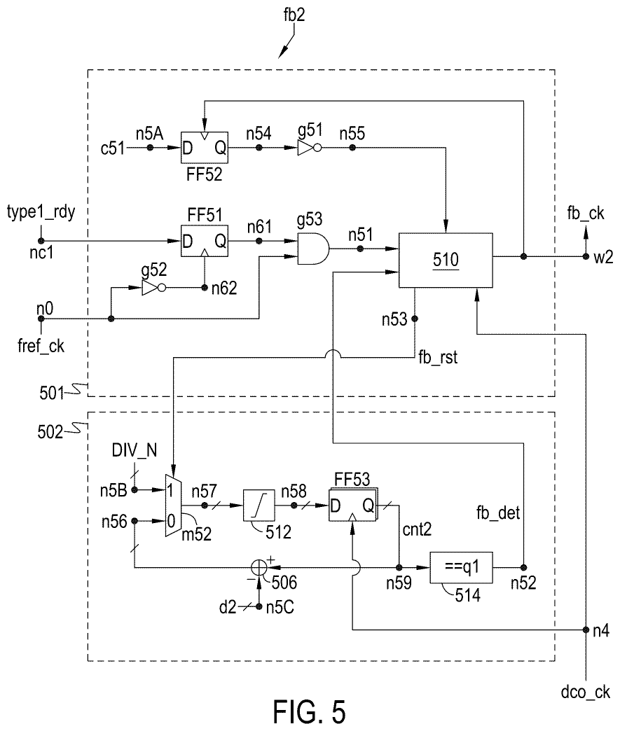

FIG. 5 illustrates an embodiment of the feedback circuit fb2 shown in FIG. 1. The feedback circuit fb2 may further comprise a feedback control block 501 and a counting block 502. The feedback control block 501 may comprise four input terminals and two output terminals respectively coupled to the signal type1_rdy at the node nc1, the clock fref_ck at the node n0, the clock dco_ck at the node n4, a node n52, the node w2 and another node n53; besides, the feedback control circuit 501 may further comprise two flipflops FF51 and FF52, a synchronization circuit 510 and three logic gates g51 to g53. The feedback control block 501 may provide a signal fb_rst at the node n53. The counting block 502 may comprise two input terminals and an output terminal respectively coupled to the nodes n53, n4 and n52; besides, the counting block 502 may further comprise a flipflop FF53, a multiplexer m52, a saturation circuit 512, a checking circuit 514 and an adder 506. The counting block 502 may provide a signal fb_det at the node n52.

Referring to FIG. 3c also, in the feedback circuit fb2 shown in FIG. 5, the feedback control block 501 may form the pulses in the clock fb_ck under triggering of the clock dco_ck according to the signal type1_rdy, the clock fref_ck and the signal fb_det, and may control a signal value of the signal fb_rst. According to an embodiment of the invention, when the signal type1_rdy (FIG. 3c) changes from the levels v1 to v2 at the time point t_rdy (FIG. 3c), the feedback control block 501 may cause the clock fb_ck to change from the levels vf1 to vf2 at the time point tb[i+2] (FIG. 3c) in response to the significant edge of the clock fref_ck at the time point tr[i+2], and may therefore form the first significant edge of the clock fb_ck. After the time point tb[i+2], according to the signal fb_det of the counting block 502 (instead of the clock fref_ck), the feedback control block 501 may determine when to cause the clock fb_ck to change back from the levels vf2 to vf1, and may determine when to form subsequent significant edges and pulses in the clock fb_ck. For example, in an embodiment, after the time point tb[i+2], the feedback control block 501 may cause the clock fb_ck to be the levels vf1 or vf2 according to whether the signal fb_det is logic 0 or logic 1. Furthermore, after the time point tb[i+2], the feedback control block 501 may also control the signal value of the signal fb_rst according to a signal value of the signal fb_det, e.g., may cause the signal fb_rst to be logic 0 or logic 1 according to whether the signal fb_det is logic 0 or logic 1.

In the feedback circuit fb2 shown in FIG. 5, the counting block 502 may accumulate and reset a count cnt2 according to the signal fb_rst under triggering of the clock dco_ck, and may provide the signal fb_det according to the count cnt2. According to an embodiment of the invention, when the signal fb_rst is logic 1, the counting block 502 may reset the count cnt2 to a number DIV_N in response to a significant edge of the clock dco_ck, and may then subtract a number d2 from the count cnt2 at each subsequent significant edge of the clock dco_ck. In addition, according to an embodiment of the invention, the counting block 502 may cause the signal fb_det to be logic 1 or logic 0 according to whether the count cont2 equals a number q1. In the counting block 502, the numbers q1, DIV_N and d2 may be three predetermined constants; in an embodiment, the numbers q1 and d2 may not equal (e.g., may be less than) the number DIV_N, e.g., the numbers q1 and d2 may equal to integer one, and the number DIV_N may be greater than integer one.

In the feedback control block 501 shown in FIG. 5, the flipflop FF51 may comprise an input terminal, an output terminal and a clock terminal respectively coupled to the signal type1_rdy at the node nc1 and another two nodes n61 and n62. The logic gate g52 may comprise an input terminal and an output terminal respectively coupled to the reference clock fref_ck at the node n0 and the node n62; in an embodiment, the logic gate g52 may be an inverter. The logic gate g53 may comprise two input terminals and an output terminal respectively coupled to the nodes n61, n0 and another node n51; in an embodiment, the logic gate g53 may be an AND gate. When the clock fref_ck changes from the levels va2 to va1, the flipflop FF51 may sample the signal type1_rdy; if a result of the sampling is the level v1 (FIG. 3c), the flipflop FF51 may cause a logic value at the node n61 to be logic 0; if the result of the sampling is the level v2 (FIG. 3c), the flipflop FF51 may cause the logic value at the node n61 to be logic 1. The synchronization circuit 510 may comprise four input terminals and two output terminals respectively coupled to a node n55, the node n51, the node n52, the node n4, the node n53 and the node w2. When a logic value at the node n55 is logic 1, the synchronization circuit 510 may form the signal fb_rst according to a signal at the node n51, e.g., may cause the signal fb_rst to equal (or to be synchronized with) the signal at the node n51. When the logic value at the node n55 is logic 0, the synchronization circuit 510 may form the signal fb_rst according to a signal at the node n52, e.g., may cause the signal fb_rst to equal (or to be synchronized with) the signal at the node n52. Besides, the synchronization circuit 510 may sample the signal fb_rst to form the clock fb_ck under triggering of the clock dco_ck.

In the feedback control block 501 shown in FIG. 5, the flipflop FF52 may comprise an input terminal, an output terminal and a clock terminal respectively coupled to two nodes n5A, n54 and the clock fb_ck at the node w2. The flipflop FF52 may sample a logic value at the node n5A at each significant edge of the clock fb_ck, and may keep outputting a result of the sampling to the node n54 until a next significant of the clock fb_ck. The node n5A may be further coupled to a number c51, which may be a predetermined constant; in an embodiment, the number c51 may equal logic 1. The logic gate g51 may comprise an input terminal and an output terminal respectively coupled to the nodes n54 and n55. In an embodiment, the logic gate g51 may be an inverter.

In the counting block 502 shown in FIG. 5, the multiplexer m52 may comprise two input terminals, an output terminal and a controlled terminal respectively coupled to three nodes n5B, n56, n57 and the signal fb_rst at the node n53. When the signal fb_rst is logic 1, the multiplexer m52 may conduct (electrically connect) the node n5B (instead of the node n56) to the node n57; when the signal fb_rst is logic 0, the multiplexer m52 may conduct the node n56 (instead of the node n5B) to the node n57. The node n5B may be further coupled to the number DIV_N. The saturation circuit 512 may comprise an input terminal and an output terminal respectively coupled to the node n57 and another node n58. When a signal value at the node n57 is between a ceiling bound (not depicted) and a floor bound (not depicted), the saturation circuit 512 may output the signal value at the node n57 to the node n58; when the signal value at the node n57 is greater than the ceiling bound or less than the floor bound, the saturation circuit 512 may cause a signal value at the node n58 to equal the ceiling bound or the floor bound, respectively. The flipflop FF53 may comprise an input terminal, an output terminal and a clock terminal respectively coupled to the node n58, another node n59 and the clock dco_ck at the node n4. The flipflop FF53 may sample the signal value at the node n58 at each significant edge of the clock dco_ck, and may output a result of the sampling to the node n59, wherein a signal value at the node n59 may be referred to as the count cnt2. The adder 506 may comprise two input terminals and an output terminal respectively coupled to the node n59, another node n5C and the node n56. The node n5C may be further coupled to the number d2. The adder 506 may subtract the number d2 from the count cnt2, and may output a result of the subtraction to the node n56. The checking circuit 514 may comprise an input terminal and an output terminal respectively coupled to the nodes n59 and n52. If the count cnt2 at the node n59 matches an internal check range, e.g., if the count cnt2 equals the number q1, then the checking circuit 514 may cause the signal fb_det at the node n52 to be logic 1; if the count cnt2 does not match the internal range, e.g., if the count cnt2 does not equal the number q1, the checking circuit 514 may cause the signal fb_det to be logic 0.

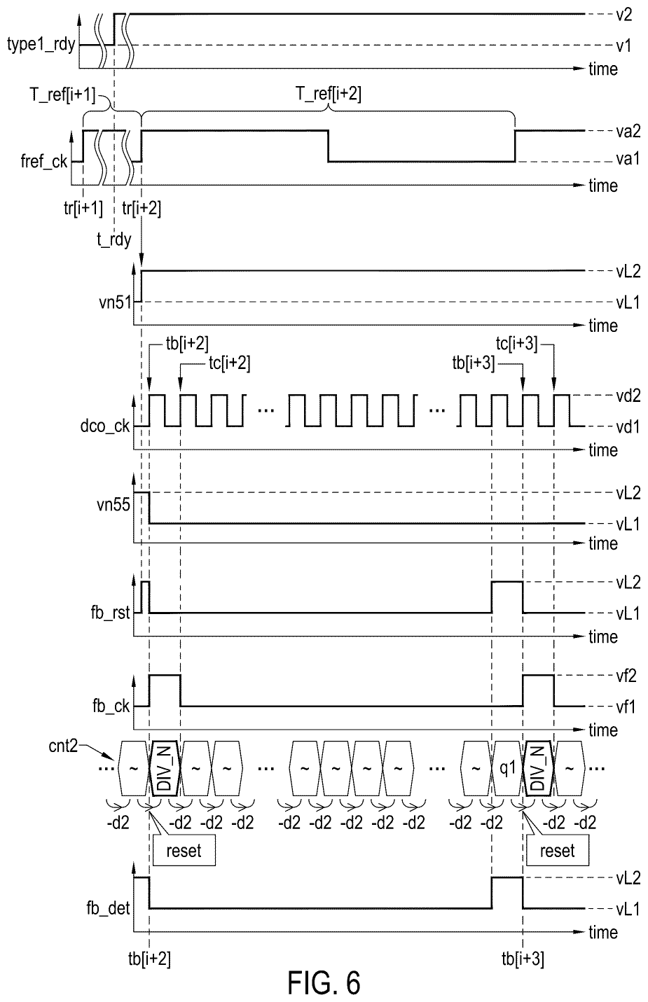

FIG. 6 illustrates waveform and timing embodiments of related signals in the feedback circuit fb2 shown in FIG. 5, wherein signals vn51 and vn55 may respectively represent voltage signals at the nodes n51 and n55. Before the time point t_rdy (also shown in FIG. 3c), when the signal type1_rdy is still of the level v1, the flipflop FF51 may cause the logic value at the node n61 to keep being the logic 0, the logic gate g53 may cause a logic value at the node n51 to be logic 0, the synchronization circuit 510 may cause the signal fb_rst at the node n53 to be logic 0 according to logic 0 at the node n51, and may cause the clock fb_ck at the node w2 to stay at the level vf1.

After the signal type1_rdy changes from the levels v1 to v2 at the time point t_rdy, in response to the significant edge of the clock fref_ck at the time point tr[i+2] (i.e., the first significant edge of the clock fref_ck after the time point t_rdy), the logic gate g53 may cause the signal vn51 at the node n51 to change from a level vL1 representing logic 0 to another level vL2 representing logic 1; therefore, the synchronization circuit 510 may cause the signal fb_rst at the node n53 to change from the levels vL1 (logic 0) to vL2 (logic 1) also at the time point tr[i+2]. Then, in response to the significant edge of the clock dco_ck at the time point tb[i+2], the synchronization circuit 510 may cause the clock fb_ck at the node w2 to change from the levels vf1 to vf2 to form the first significant edge of the clock fb_ck.

In response to the first significant edge of the clock fb_ck at the time point tb[i+2], the flipflop FF52 may cause a logic value at the node n54 to equal a logic value of the number c51, e.g., logic 1; as a result, the logic gate g51 may cause the signal vn55 at the node n55 to change from the levels vL2 (logic 1) to vL1 (logic 0). After the time point tb[i+2], the flipflop FF52 and the logic gate g51 may cause the signal vn55 at the node n55 to stay at the level vL1 (logic 0), so the synchronization circuit 510 may form the signal fb_rst according to the signal fb_det (e.g., may cause the signal fb_rst at the node n53 to equal the signal fb_det at the node n52).

When the logic gate g53 and the synchronization circuit 510 cause the node n51 and the signal fb_rst at the node n53 to change from logic 0 to logic 1 in response to the significant edge of the clock fref_ck at the time point tr[i+2], the multiplexer m52 in the counting block 502 may conduct the node n5B to the node n57, so the flipflop FF53 may cause the count cnt2 to equal the number DIV_N in response to the significant edge of the clock dco_ck at the time point tb[i+2], and hence the checking circuit 514 may cause the signal fb_det at the node n52 to be the level vL1 (logic 0).

After the significant edge of the clock dco_ck at the time point tb[i+2], the synchronization circuit 510 may form the signal fb_rst according to the signal fb_det. Therefore, in response to the next significant edge of the clock dco_ck at the time point tc[i+2], the synchronization circuit 510 may sample logic 0 of the signal fb_det, and may then cause the clock fb_ck at the node w2 to change back from the levels vf2 to vf1; the adder 506 may subtract the number d2 from the count cnt2, and the flipflop FF53 may cause the count cnt2 to equal a number (DIV_N−d2). In response to a subsequent significant edge of the clock dco_ck (e.g., at time point tc[i+2]+T_dco, not depicted), the adder 506 may subtract the number d2 from the count cnt2 again, and the flipflop FF53 may cause the count cnt2 to equal a number (DIV_N−2*d2). That is, in the counting block 502, the flipflop FF53 may first reset the count cnt2 to the number DIV_N in response to the significant edge of the clock dco_ck at the time point tb[i+2]; after the time point tb[i+2], the adder 506 and the flipflop FF53 may cause the number d2 to be subtracted from the count cnt2 at each subsequent significant edge of the clock dco_ck.

In an embodiment, the number DIV_N may relate to the numbers d2, q1 and N_fb (FIG. 3c). For example, in an embodiment, the number DIV_N may equal a number ((N_fb−1)*d2+q1); therefore, when a number (Nfb−1) of the period lengths T_dco elapse after the time point tb[i+2], the adder 506 and the flipflop FF53 may cause the count cnt2 to equal the number q1. The checking circuit 514 may then cause the signal fb_det at the node n52 to change to the level vL2 (logic 1), and the synchronization circuit 510 may cause the signal fb_rst at the node n53 to change to the level vL2 (logic 1); in response to the significant edge of the clock dco_ck at the time point tb[i+3] (i.e., a time point (tb[i+2]+N_fb*T_dco)), the synchronization circuit 510 may cause the clock fb_ck at the node w2 to change from the levels vf1 to vf2 to form the significant edge of the clock fb_ck at the time point tb[i+3], and the flipflop FF53 may reset the count cnt2 to the number DIV_N.

After the count cnt2 is reset to the number DIV_N at the time point tb[i+3], the checking circuit 514 and the synchronization circuit 510 may cause the signals fb_det and fb_rst at the nodes n52 and n53 to change back to logic 0. Therefore, in response to a first significant edge of the clock dco_ck after the time point tb[i+3] (i.e., in response to the significant edge of the clock dco_ck at the time point tc[i+3]), the synchronization circuit 510 may cause the clock fb_ck to change back from the levels vf2 to vf1, the adder 506 and the flipflop FF53 may cause the number d2 to be subtracted from the count cnt2, so the count cnt2 may equal the number (DIV_N−d2).

To sum up, the invention may provide a phase lock loop with improved performance, as well as a related method, such as the PLL 100 in FIG. 1 and the method regarding its operations. The invention may rapidly accomplish frequency and phase lock, and may reduce time and power required to lock frequency and phase. In an embodiment of the invention, the PLL 100 may first achieve fast frequency lock according to the mode in FIG. 2a, and may then achieve fast phase lock according to the mode in FIG. 2b. As shown in FIG. 2a, the first detector fd1 may cause the ready signal type1_rdy to be the level v1 (FIG. 3c), may count how many period lengths T_sys (FIG. 3a) of the system clock sys_ck are covered in one period length T_ref (FIG. 3a) of the reference clock fref_ck to detect the frequency difference between the reference clock fref_ck and the system clock sys_ck, and may reflect a result of the counting by the frequency error signal freq_err (FIG. 3b) and the first error signal fd_err (FIG. 1, FIG. 2a and FIG. 2d); besides, the first detector fd1 may determine whether to cause the ready signal type1_rdy to change from the levels v1 to v2 according to values of the signal freq_err at different periods of the reference clock fref_ck (e.g., the values freq_err[i−1], freq_err[i] and freq_err[i+1] in FIG. 3b, etc.). By coordinating the signal fd_err, the signal s1 and the gain of the oscillator O1, the PLL 100 may rapidly accomplish frequency lock according to the mode in FIG. 2a, and the first detector fd1 may cause the ready signal type1_rdy to change to the level v2. As shown in FIG. 2b, when the signal type1_rdy is of the level v2, the feedback circuit fb2 may provide the feedback clock fb_ck according to the ready signal type1_rdy, the reference clock fref_ck and the oscillation clock dco_ck, the second detector pfd2 may measure the time difference between each significant edge of the reference clock fref_ck (e.g., tr[i+2], tr[i+3] in FIG. 3c, etc.) and a corresponding significant edge of the feedback clock fb_ck (e.g., tb[i+2], tb[i+3] in FIG. 3c, etc.) to detect the phase difference between the reference clock fref_ck and the feedback clock fb_ck, and may therefore generate the second error signal pfd_err. Because the feedback circuit fb2 may form the first significant edge of the feedback clock fb_ck (e.g., the significant edge at the time point tb[i+2], FIG. 3c) in response to a certain significant edge of the reference clock fref_ck (e.g., the significant edge at the time point tr[i+2], FIG. 3c), the feedback circuit fb2 may cause each significant edge of the feedback clock fb_ck to approach a corresponding significant edge of the reference clock fref_ck, and may then facilitate the PLL 100 to rapidly accomplish phase lock.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A phase lock loop (PLL) with improved performances, comprising:
a first detector coupled to a reference node, a frequency-division node, a first node and a lock-control node;
a second detector coupled to the reference node, a feedback node and a second node;
a multiplexer comprising two input terminals, a controlled terminal and an output terminal respectively coupled to the first node, the second node, the lock-control node and a filter node;
a filter coupled to the filter node and a third node;
an oscillator coupled to the third node and a fourth node;
a frequency-divider coupled to the fourth node and the frequency-division node; and
a feedback circuit coupled to the reference node, the fourth node, the lock-control node and the feedback node; wherein:
the reference node is coupled to a reference clock;
the filter provides an oscillation control signal at the third node according to a signal at the filter node;
the oscillator generates an oscillation clock at the fourth node according to the oscillation control signal;
the frequency-divider performs frequency division on the oscillation clock to generate a system clock at the frequency-division node;
the first detector provides a ready signal at the lock-control node;
when the ready signal is of a first level, the first detector further detects a frequency difference between the reference clock and the system clock, provides a first error signal at the first node according to the frequency difference, and determines whether to cause the ready signal to change from the first level to a second level according to the frequency difference; and, the multiplexer electrically connects the first node to the filter node; and
when the ready signal is of the second level, the feedback circuit provides a feedback clock at the feedback node according to the oscillation clock, the second detector detects a phase difference between the reference clock and the feedback clock to accordingly generate a second error signal at the second node, and the multiplexer electrically connects the second node to the filter node.

2. The PLL of claim 1, wherein the filter comprises:
a first filtering circuit coupled to the filter node and a first middle node;
a second filtering circuit coupled to a second filter node and a second middle node; and
a third filtering circuit coupled to the first middle node, the second middle node and the third node.

3. The PLL of claim 2 further comprising:
a switch coupled between the second node and the second filter node; wherein:
when the ready signal is of the first level, the switch does not electrically connect the second node to the second filter node; and
when the ready signal is of the second level, the switch electrically connects the second node to the second filter node.

4. The PLL of claim 2, wherein:
when the ready signal is of the first level, the first filtering circuit performs signal processing on the first error signal to provide a first filter signal at the first middle node, and the third filtering circuit forms the oscillation control signal according to the first filter signal; and
when the ready signal is of the second level, the first filtering circuit performs signal processing on the second error signal to provide the first filter signal at the first middle node, the second filtering circuit performs signal processing on the second error signal to provide a second filter signal at the second middle node, and the third filtering circuit forms the oscillation control signal jointly according to the first filter signal and the second filter signal.

5. The PLL of claim 4, wherein:
when the ready signal is of the first level, the third filtering circuit forms the oscillation control signal by performing signal processing on the first filter signal; and
when the ready signal is of the second level, the third filtering circuit forms the oscillation control signal by performing signal processing on a linear combination of the first filter signal and the second filter signal.

6. The PLL of claim 1, wherein:
the first detector comprises a reference clock edge detector, a reference clock counter and a lock detector;
the reference clock edge detector is coupled to the reference node, the frequency-division node and a first connection node;
the reference clock counter is coupled to the first connection node, a second connection node and the frequency-division node;
the lock detector is coupled to the first connection node, the second connection node, the frequency-division node and the lock-control node;
the reference clock edge detector detects each edge of the reference clock occurring when the reference clock changes from a first reference clock level to a second reference clock level, and accordingly provides an indication signal at the first connection node;
the reference clock counter accumulates and resets an internal count according to the indication signal, and provides a frequency error signal at the second connection node according to the internal count;
the lock detector controls level of the ready signal according to the frequency error signal; and
the first detector provides the first error signal according to the frequency error signal.

7. The PLL of claim 6, wherein:
when the reference clock edge detector detects each said edge of the reference clock, the reference clock edge detector causes the indication signal to change from a first indication level to a second indication level, and causes the indication signal to change back from the second indication level to the first indication level after a first pulse width.

8. The PLL of claim 7, wherein the first pulse width equals a length of a period of the system clock.

9. The PLL of claim 6, wherein:
when the reference clock counter accumulates and resets the internal count according to the indication signal, the reference clock counter accumulates and resets the internal count according to the indication signal under triggering of the system clock.

10. The PLL of claim 6, wherein:
when the reference clock counter provides the frequency error signal according to the internal count, the reference clock counter causes a current value of the internal count to relate to how many periods of the system clock are included in a corresponding period of the reference clock, and sets a current value of the frequency error signal according to the current value of the internal count.

11. The PLL of claim 6, wherein:
when the lock detector controls the level of the ready signal according to the frequency error signal, the lock detector checks whether a current value of the frequency error signal causes a predetermined condition to be satisfied, and accordingly controls whether the ready signal is of the second level or the first level.

12. The PLL of claim 1, wherein:
the first detector comprises:
a first interior flipflop comprising an input terminal, an output terminal and a clock terminal respectively coupled to the reference node, a first interior node and the frequency-division node;
a second interior flipflop comprising an input terminal, an output terminal and a clock terminal respectively coupled to the first interior node, a second interior node and the frequency division node;
a first interior logic gate comprising an input terminal and an output terminal respectively coupled to the second interior node and a third interior node; and
a second interior logic gate comprising two input terminals and an output terminal respectively coupled to the third interior node, the first interior node and a fourth interior node.

13. The PLL of claim 12, wherein:
the second interior logic gate is an AND gate.

14. The PLL of claim 1, wherein:
the feedback circuit comprises:
a first internal flipflop comprising an input terminal, an output terminal and a clock terminal respectively coupled to the lock-control node, a first front node and a second front node;
a second internal logic gate comprising an input terminal and an output terminal respectively coupled to the reference node and the second front node; and
a third internal logic gate comprising two input terminals and an output terminal respectively coupled to the first front node, the reference node and a first internal node.

15. The PLL of claim 14, wherein:
the third internal logic gate is an AND gate.

16. The PLL of claim 14, wherein:
the feedback circuit further comprises a second internal flipflop and a third internal flipflop;
the second internal flipflop comprises a clock terminal coupled to the feedback node; and
the third internal flipflop comprises a clock terminal coupled to the fourth node.

17. The PLL of claim 1, wherein:
after the ready signal changes from the first level to the second level, the feedback circuit forms a significant edge in the feedback clock in response to an edge of the reference clock, and forms a subsequent significant edge in the feedback clock after a predetermined interval; and
each said significant edge of the feedback clock is an edge of the feedback clock occurring when the feedback clock changes from a first feedback clock level to a second feedback clock level.

18. The PLL of claim 17, wherein the predetermined interval is a product of a predetermined multiplication number and a period of the oscillation clock.

19. A method for a phase lock loop (PLL); the PLL comprising an oscillator, the oscillator generating an oscillation clock according to an oscillation control signal, and the method comprising:
forming a significant edge in a feedback clock in response to an edge of a reference clock, and forming a subsequent significant edge in the feedback clock after a predetermined interval;
detecting a phase difference between the reference clock and the feedback clock to generate an error signal; and
providing the oscillation control signal according to the error signal; wherein:
each said significant edge of the feedback clock is an edge of the feedback clock occurring when the feedback clock changes from a first feedback clock level to a second feedback clock level.

20. The method of claim 19, wherein the predetermined interval is a product of a predetermined multiplication number and a period of the oscillation clock.
